(19) United States
(12) Patent Application Publication
(10) Pub. No.: US 2022/0085082 A1
(43) Pub. Date: Mar. 17, 2022

(54) ELECTRONIC DEVICE COMPRISING A PHOTOSENSITIVE SEMICONDUCTOR REGION AND CORRESPONDING MANUFACTURING METHOD

(71) Applicant: STMicroelectronics (Crolles 2) SAS, Crolles (FR)

(72) Inventors: Axel CROCHERIE, Grenoble (FR); Stephane MONFRAY, Eybens (FR)

(73) Assignee: STMicroelectronics (Crolles 2) SAS, Crolles (FR)

(21) Appl. No.: 17/469,702

(22) Filed: Sep. 8, 2021

(30) Foreign Application Priority Data
Sep. 11, 2020 (FR) 2009212

(51) Int. Cl. H01L 27/146

(52) U.S. Cl. CPC H01L 27/1464; H01L 27/14629

(57) ABSTRACT

A photosensitive semiconductor region is configured to be illuminated through a rear face. A periodic array of pads formed of a first material is provided at the front face. The periodic array has an outline with a periodic pattern parameterized by characteristic dimensions. The outline forms an interface between the first material and a second material, where the first and second materials have different optical indices. The characteristic dimensions of the periodic pattern are less than a wavelength of interest and are configured to produce at the interface a reflection of light at the wavelength of interest towards the photosensitive semiconductor region.

### PRIORITY CLAIM

This application claims the priority benefit of French Application for Patent No. 2009212, filed on Sep. 11, 2020, the content of which is hereby incorporated by reference in its entirety to the maximum extent allowable by law.

### TECHNICAL FIELD

Embodiments and implementations relate to the field of microelectronics and, more particularly, to the field of light sensors.

### BACKGROUND

Conventional electronic devices comprise, for example, a back-side illuminated light sensor of the “BSI” type (acronym of the usual term “Back Side Illumination”) comprising at least one pixel and an associated photosensitive area. The photosensitive area comprises a lower face and an upper face.

The lower face of the photosensitive area receives light rays. The upper face of the photosensitive area is covered by an isolating layer of the “PMD” (acronym for the usual term “Pre-Metal Dielectric”) type electrically isolating the upper face of metal layers from an interconnection network.

The light rays coming from the rear face and not having been absorbed by the photosensitive area escape through the upper face of the photosensitive area via the isolating layer. In this regard, a reflective plate is conventionally placed in a first metal level of the interconnection network so as to reflect the light rays escaping from the photosensitive area.

Such dispositions have disadvantages insofar as some light rays are reflected outside the photosensitive area, these light rays being able to pass through an optical path existing in the “PMD” type isolating layer.

The light rays reflected outside the photosensitive area are not absorbed in the photosensitive area, which in particular limits the sensitivity of the associated pixel.

Moreover, the light rays reflected outside the photosensitive area can disturb the operation of neighboring areas.

This is particularly the case when the light rays are detected in neighboring photosensitive areas, these rays introduce a light signal interfering in the neighboring photosensitive areas, usually called “cross talk”.

This is also the case when the light rays reach charge transfer areas, the light rays then being able to generate parasitic charges altering, for example, the information contained in the area, this is referred to as “Parasitic Light Signal”.

Thus, it is desirable to increase the amount of light rays reflected towards the photosensitive area in order to decrease the various parasitic signals and to improve light absorption in the photosensitive area.

### SUMMARY

According to one aspect, provision is made of an electronic device comprising: a photosensitive semiconductor region configured to be illuminated through a rear face, comprising a front face opposite the rear face, a periodic array of pads, comprising a first material, formed on the front face, having an outline having a periodic pattern parameterized by characteristic dimensions, said outline forming an interface between the first material and a second material, the second material having an optical index different from an optical index of the first material, wherein the characteristic dimensions of the periodic pattern are less than a wavelength of interest and are configured to produce a reflection of light on the interface, at the wavelength of interest, towards the photosensitive semiconductor region.

In other words, the characteristic dimensions of the periodic pattern of the outline of the array are configured to produce, on light rays at the wavelength of interest, constructive light interference below the front face of the photosensitive semiconductor region, and destructive light interference above the front face of the photosensitive semiconductor region.

Thus, the periodic array of pads is configured to exploit a resonance effect in order to produce light reflection at the wavelength of interest.

In addition, given that the periodic array of pads is located on the front face of the photosensitive region, there is no optical path between the reflection surface (it will be considered that the reflection surface is represented by the outline of the periodic array) and a region of the device other than the photosensitive region.

According to one embodiment, the pads project relative to the front face of the photosensitive semiconductor region, and the second material belongs to a dielectric layer covering the projecting pads and the front face.

Thus, the pads projecting relative to the front face of the photosensitive semiconductor region can be formed by additions of material, for example in a manner similar to the formation of gate regions of transistors.

According to an alternative embodiment, the pads are housed in trenches penetrating into the photosensitive semiconductor region, the pads are included in a dielectric layer filling the trenches and covering the front face of the photosensitive semiconductor region, and the second material belongs to the photosensitive semiconductor region.

Thus, the second material being the semiconductor material of the photosensitive region, the interface on which the reflection occurs is located in the photosensitive semiconductor region.

In addition, the trenches housing the pads can be formed, for example, similarly to shallow isolation trenches.

According to one embodiment, each pad has a shape of a cylinder including a diameter and a height, the characteristic dimensions comprising said diameter and said height.

Thus, each cylindrical pad has an axial symmetry to isotropically reflect incident light rays relative to the axis of symmetry of each cylinder.

The reflection is thus advantageously neutral relative to a possible polarization of the light and an angle of incidence of the light.

According to one embodiment, the periodic array of pads is disposed in a periodic arrangement comprising an elementary mesh of pads repeated with a fixed period, the characteristic dimensions comprising said fixed period.

Indeed, the disposition of the pads of the array in a mesh, that is to say a periodic array whose elementary mesh is, for example, one of rectangular, square, or hexagonal (without these examples being limiting), allows a simple and versatile design to uniformly cover the front face of the photosensitive region with pads.

In addition, the fixed period of repetition of the elementary mesh is less than the wavelength of interest.

Thus, the fixed period of repetition of the mesh contributes in producing the resonance effect allowing the reflection of light at the wavelength of interest, and the periodic arrangement of the mesh allows the uniform reflection of light at the wavelength of interest on the front face of the photosensitive region.

According to one embodiment, the photosensitive semiconductor region is configured to specifically detect light at wavelengths centered on the wavelength of interest.

“Wavelengths centered on the wavelength of interest” means a substantially uniform distribution of wavelengths, centered on the wavelength of interest, and whose width is narrowly defined by a material selection tolerance of the wavelength of interest. This is for example the case with sensors such as “time-of-flight” sensors, the detected signal of which is filtered at the wavelength of interest, that is to say the wavelength of the time-of-flight signal emitted by the detector.

Indeed, the reflection being selective on the wavelength of interest, the device according to this aspect is particularly advantageous when the photosensitive semiconductor region is specifically dedicated to the wavelength of interest.

According to one embodiment, the first material and the second material are selected from the following materials: polycrystalline silicon, silicon oxide, silicon nitride, monocrystalline silicon, so as to have a difference in optical index adjusted according to the characteristic dimensions of the periodic array, in order to produce the reflection of light at the wavelength of interest on the interface.

Indeed, the materials exposed above are materials usually used for the manufacture of integrated circuits, their use is therefore controlled and inexpensive in the overall context of industrial methods.

According to one embodiment, the device comprises transistors having gate regions made of polycrystalline silicon, the first material having the same nature and the same thickness as the gate regions of the transistors.

Thus, the pads can be formed during common formation steps with transistor gate regions, this allows the device to be manufactured according to this aspect free of charge in a context providing for conventional methods.

According to one embodiment, the device comprises shallow isolation trenches, wherein the trenches penetrating into the photosensitive semiconductor region and running along the pads have the same nature and the same depth as said shallow isolation trenches.

Thus, the pads can be formed during steps of etching shallow isolation trenches, this allows the device to be manufactured according to this aspect free of charge in a context providing for conventional methods.

According to another aspect, provision is made of a method for manufacturing an electronic device comprising: forming a photosensitive semiconductor region configured to be illuminated through a rear face, comprising a front face opposite the rear face; and forming a periodic array of pads from a first material, on the front face, so that an outline of the periodic array has a periodic pattern parameterized by characteristic dimensions so as to form an interface between the first material and a second material, the second material having an optical index different from the optical index of the first material; wherein the characteristic dimensions of the periodic pattern are formed at dimensions less than a wavelength of interest and configured to produce a reflection of light at the interface, at the wavelength of interest, towards the photosensitive semiconductor region.

According to one implementation, the formation of the periodic array of pads comprises: forming a layer of the first material on the front face of the photosensitive semiconductor region; etching in the layer of the first material, so as to form pads projecting relative to the front face of the photosensitive semiconductor region; and forming a dielectric layer comprising the second material and covering the projecting pads.

According to one alternative implementation, the formation of the periodic array of pads comprises: etching trenches penetrating the photosensitive semiconductor region comprising the second material, so as to form the outline of the periodic array; and filling said trenches with a dielectric layer comprising the first material, so as to house the pads in the trenches.

According to one implementation, each pad of the periodic array is formed so as to have a shape of a cylinder including a diameter and a height, the characteristic dimensions comprising said height and said diameter.

According to one implementation, the periodic array is formed so that the pads are disposed in a periodic arrangement comprising an elementary mesh of pads repeated with a fixed period, the characteristic dimensions comprising said fixed period.

In one implementation, the photosensitive semiconductor region is configured specifically to detect light at wavelengths centered on the wavelength of interest.

According to one implementation, the first material and the second material are selected from the following materials: polycrystalline silicon, silicon oxide, silicon nitride, monocrystalline silicon, so as to have a difference in optical index adjusted according to the characteristic dimensions of the periodic array, in order to produce the reflection of light at the wavelength of interest on the interface.

According to one implementation, the method further comprises a formation of gate regions of transistors including: forming a layer of polycrystalline silicon; and etching the gate regions of the transistors in the polycrystalline silicon layer; wherein the formation of the layer of the first material is carried out simultaneously with the formation of the polycrystalline silicon layer, and the etching in the layer of the first material is carried out simultaneously with the etching of the gate regions of transistors in the polycrystalline silicon layer.

According to one implementation, the method further comprises forming shallow isolation trenches, wherein: etching of trenches penetrating the photosensitive semiconductor region is carried out simultaneously with an etching of shallow isolation trenches; and filling of the trenches with a dielectric layer is carried out simultaneously with a filling of the shallow isolation trenches.

### BRIEF DESCRIPTION OF THE DRAWINGS

Other advantages and features of the invention will become apparent upon examining the detailed description of embodiments and implementations, which are in no way limiting, and the appended drawings wherein:

FIG. 1 illustrates a sectional view of a device comprising a light sensor;

FIGS. 2 and 3 illustrate pads disposed in an arrangement comprising a repeated polygonal elementary mesh with a period;

FIG. 4 illustrates an alternative arrangement for the periodic array of pads;

FIG. 5 is a graph illustrating results of a simulation of the reflection of light on a periodic array of cylindrical pads belonging to a device similar to the device described with reference to FIGS. 1, 2 and 3;

FIG. 6 illustrates steps of a method for manufacturing a periodic array of pads;

FIG. 7 illustrates steps of a method for manufacturing a periodic array of pads; and

FIG. 8 illustrates steps of an alternative to the method of FIG. 6 for manufacturing a periodic array of pads.

### DETAILED DESCRIPTION

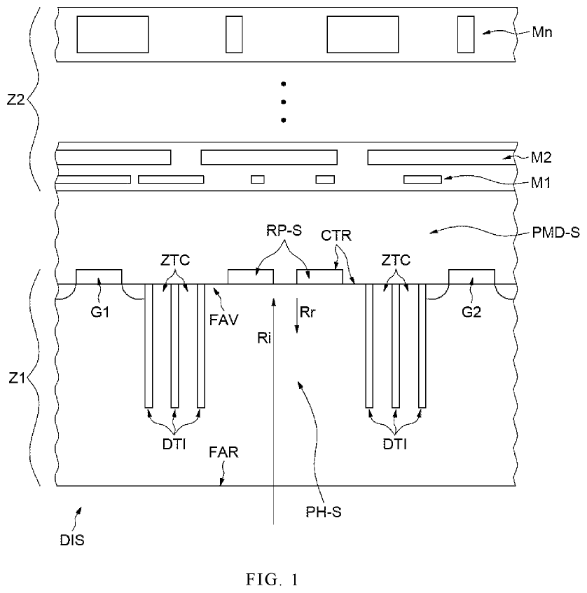

FIG. 1 illustrates a sectional view of a device DIS comprising a light sensor, for example a sensor of the “BSI” (acronym for the term “Back Side Illumination”) type.

The device DIS comprises a photosensitive semiconductor region PH-S having a pixel including a front face FAV having a periodic array of pads RP-S, a rear face FAR configured to receive incident light rays Ri, and side faces framed by deep isolation trenches DTI (usually called “Deep Trench Isolation”).

The periodic array of pads RP-S and free portions of the front face FAV are covered by a pre-metal dielectric layer PMD-S. It will be considered that the surface of the front face FAV may or may not be covered with a layer of native oxide. Native oxide layers on semiconductor regions are typically present in industrial methods and sometimes removed, and their mention may be intentionally omitted for the sake of brevity.

Moreover, the pads of the periodic array RP-S may or may not be separated from the front face FAV by an oxide layer similar to an oxide layer of the gate of a “MOSFET” (acronym for the usual term “Metal Oxide Semiconductor Field Effect Transistor”) type transistor.

The photosensitive semiconductor region PH-S is, for example, configured specifically to detect wavelengths centered on a wavelength of interest. The wavelength of interest is, for example, an infrared wavelength used in the context of a “TOF” (acronym of the usual term “Time Of Flight”) type application.

The device DIS comprises a first area Z1 including active components usually designated by the acronym “FEOL” (for “Front End Of Line”), and a second area Z2 comprising connection elements usually designated by the acronym “BEOL” (for “Back End Of Line”). By convention, the vertical orientation is selected such that the second area Z2 is located above the first area Z1.

The first area Z1 comprises elements such as transistors G1, G2, the photosensitive region PH-S, and charge transfer areas ZTC. The second area Z2 comprises a metallic interconnection network comprising a plurality of metal levels M1, M2, Mn superimposed on top of the dielectric layer PMD-S.

The charge transfer areas ZTC are configured to receive charges generated in the photosensitive semiconductor region PH-S by light rays. The charge transfer areas ZTC can be disturbed by any light rays passing therethrough, and parasitic charges can be generated, therefore altering the information contained in the area; this is referred to as a “Parasitic Light Signal”.

In this regard, the periodic array of pads RP-S is provided on the front face FAV of the photosensitive semiconductor region PH-S to reflect part of the incident light rays Ri coming from the rear face FAR, in the direction of the photosensitive region PH-S. The reflected light rays Rr can thus be detected in the photosensitive semiconductor region PH-S.

The periodic array of projecting pads RP-S is a set of identical pads disposed in a periodic arrangement on the front face FAV of the photosensitive semiconductor region PH-S.

The pads of the periodic array are formed from a first material, for example polycrystalline silicon. The dielectric layer PMD-S covering the pads of the periodic array is formed from a second material, for example silicon oxide.

An outline CTR of the periodic array RP-S is located at an interface between the first material and the second material and on portions of the front face FAV not occupied by pads.

The periodic array RP-S of pads, in particular the outline CTR of the array, comprises characteristic dimensions less than the wavelength of interest and the interface between the first material and the second material has a difference in optical index.

Such an interface, the dimensions of which are less than the wavelength of interest, is called a “meta-surface”. A meta-surface is well known to the person skilled in the art, who may nevertheless refer, for all practical purposes, to the scientific publication by Yu and al. “Light Propagation with Phase Discontinuities: Generalized Laws of Reflection and Refraction,” SCIENCE vol. 334, Oct. 21, 2011 (incorporated by reference), which gives an example of the definition of a meta-surface.

The interface is intended to allow light reflection by exploiting particular resonance properties allowing perfect constructive interference to be obtained below the periodic array RP-S and perfect destructive interference to be obtained above the periodic array.

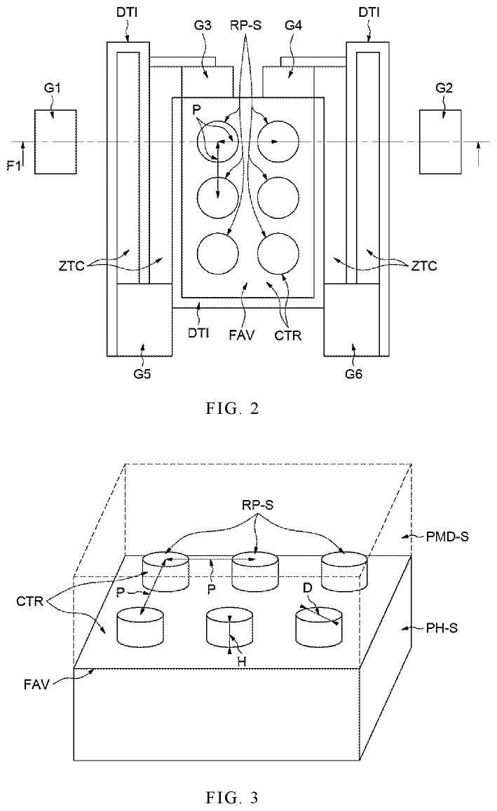

The pads are disposed in an arrangement comprising a repeated polygonal elementary mesh with a period P (FIGS. 2 and 3). In particular, the fixed period P of repetition of the meshes in the array corresponds to a spacing between two similar corners of two contiguous meshes.

An elementary mesh of the periodic array RP-S comprises the same periodic pattern comprising one or more pads each located at the corners of the polygon.

For example, the pads can be disposed in a square or rectangular mesh grid, or else in an arrangement of hexagonal meshes forming a “honeycomb” type mesh.

In the following, the periodic arrangement described is a grid, this example not being limiting.

The elementary mesh period P of repetition belongs to the characteristic dimensions of the periodic array RP-S. Likewise, the periodic pattern comprises dimensions belonging to the characteristic dimensions of the periodic array RP-S. In a case where the pads are cylinders, for example, the characteristic dimensions of the periodic array comprise the diameter and the height of the cylinders. Of course, the pads can be of a different shape, which is, for example, hemispherical or parallelepipedal.

In addition, the difference in optical index between the first and the second material as well as the characteristic dimensions of the array are configured to cause a specific phase shift of the incident ray Ri so as to obtain a reflection of light Rr in the direction of the rear face FAR.

Briefly, the materials selected and the periodic pattern of the outline of the array RP-S are configured to produce constructive light interference below the front face of the photosensitive semiconductor region and destructive light interference above the front face of the photosensitive semiconductor region, on incident light rays Ri at the wavelength of interest in order to generate the reflection Rr.

FIG. 2 illustrates a top view of the first area Z1 of the device DIS of FIG. 1. A section plane F1 allows the sectional view shown in FIG. 1 to be located in relation to the view illustrated in FIG. 2.

The front face FAV of the photosensitive semiconductor region occupies a surface, for example of rectangular shape.

The periodic array of pads RP-S includes in this example a rectangular-shaped grid comprising six pads disposed on the front face FAV. Of course, the grid can take any shape to adapt to the surface occupied by the front face FAV of the photosensitive semiconductor region.

The six-pad grid comprises two pads across the width and three pads across the length. Likewise, the grid may comprise any number of pads to adapt to dimensions of the surface occupied by the front face FAV.

The grid comprises in this embodiment a fixed spacing between the pads P, defining a period of the periodic pattern. Alternatively, the spacing between the pads may be different depending on the directions of the grid.

The front face FAV of the photosensitive semiconductor region is framed by deep isolation trenches DTI, defining charge transfer area ZTC walls. The charge transfer areas ZTC are isolated from the photosensitive semiconductor region in particular by the deep isolation trenches DTI and allow the photo-generated charges to be temporarily stored in the photosensitive region during a reading following an image acquisition.

Gate regions G1, G2, G3, G4, G5, G6 of transistors are disposed, for example, in the same plane as the periodic array of pads RP-S. The gate regions G3, G4, G5 and G6, for example, belong to transistors allowing charge transfers between the photosensitive semiconductor region PH-S, the charge transfer areas ZTC and read channels.

FIG. 3 illustrates a periodic array RP-S comprising projecting pads disposed on a front face FAV of a photosensitive semiconductor region PH-S. A dielectric layer PMD-S covers the periodic array RP-S of projecting pads and portions of the front face FAV.

The projecting pads of the periodic array RP-S are projecting cylinders deposited on the front face FAV of the photosensitive semiconductor region PH-S. The projecting cylinders comprise a diameter D and a height H, the periodic array of projecting cylinders is disposed in a grid including a fixed spacing P between the axis of revolution of each cylinder.

Thus, the periodic array RP-S includes an outline CTR matching cylindrical shapes projecting relative to the front face FAV of the photosensitive semiconductor region PH-S.

The projecting cylinders are formed from a first material, for example polycrystalline silicon, and the dielectric layer PMD-S is formed from a second material, for example silicon oxide.

The projecting cylinders can advantageously be produced at the same time as at least some of the regions of the gates G1-G6 and consequently include layers of materials of the same nature and of the same thickness, that is to say of the same chemical composition and of the same crystallographic features, as the gate regions of transistors, G1, G2, G3, G4, G5, and G6.

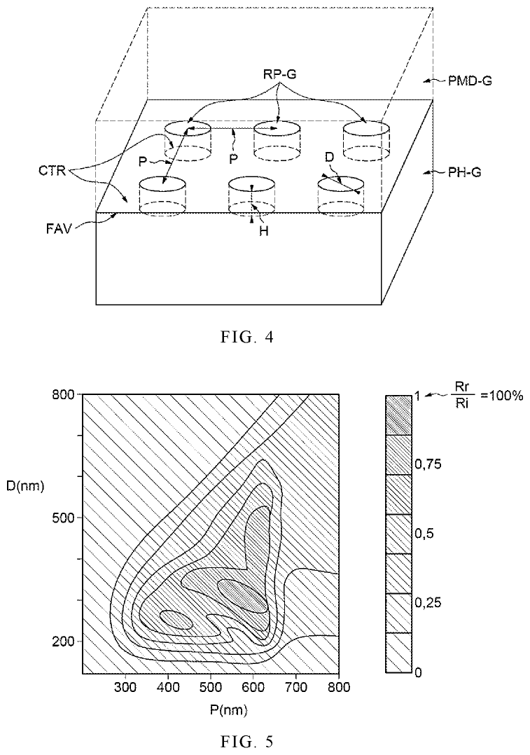

FIG. 4 illustrates an alternative of the periodic array RP-G of pads, wherein the pads are housed in trenches penetrating into a photosensitive semiconductor region PH-G.

The photosensitive semiconductor region PH-S comprises etched trenches in the shape of cylinders penetrating into the front face FAV. The cylinder-shaped trenches have a depth, equivalent to a height H, and a diameter D.

A dielectric layer PMD-G fills the trenches so as to form the pads of the periodic array matching the shapes of etched cylinders of the trenches. The cylinder-shaped trenches are disposed in a grid including a fixed spacing P between the axis of revolution of each etched cylinder.

Thus, the periodic array of pads RP-G has an outline CTR matching cylindrical shapes etched in the photosensitive semiconductor region PH-G.

The pads housed in the semiconductor region are formed from a first material, for example, silicon oxide, and the photosensitive semiconductor region PH-G is formed from a second material, for example, the semiconductor material of the photosensitive region PH-G.

The silicon oxide pads housed in the trenches can be obtained by a method similar to forming shallow isolation trenches.

Here again, the difference in optical index between the first and the second material, as well as the characteristic dimensions of the array, are configured to cause a specific phase shift of the incident ray Ri so as to obtain a reflection of light Rr in the direction of the rear face FAR.

FIG. 5 illustrates a graph showing the results of a simulation of the reflection of light on a periodic array of cylindrical pads RP-S belonging to a device similar to the device described with reference to FIGS. 1, 2 and 3.

The graph is drawn for an incident light signal parameterized at the wavelength of 940 nanometers (that is to say the wavelength of interest), and for a constant height H of 200 nanometers of the cylindrical pads.

The graph shows a reflection rate Rr/Ri as a function of the period P of the array, on the abscissa, and as a function of the diameter D of the cylindrical pads, on the ordinate. The reflection rate Rr/Ri corresponds to the amount of reflected rays Rr on the amount of incident rays Ri.

The graph shows reflection maxima Rr/Ri reaching 90% for diameters D comprised between 250 and 350 nanometers and periods P comprised between 580 and 620 nanometers.

Thus, the characteristic dimensions of the periodic pattern can advantageously be parametrized by being in these intervals, and, for example, cylindrical pads having a diameter D of 300 nanometers, a height of 200 nanometers arranged in a regular grid having a period P of 600 nanometers, can be formed.

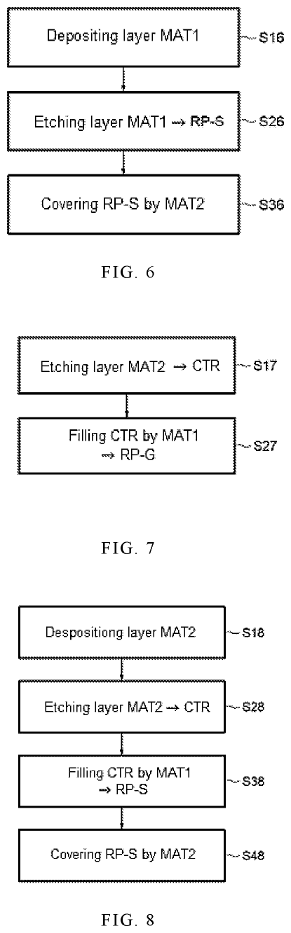

FIG. 6 illustrates the steps of a method for manufacturing a periodic array RP-S of pads projecting on a front face FAV of a photosensitive semiconductor region PH-S.

A first step S16 comprises forming a layer of a first material MAT1 on the front face FAV of the photosensitive semiconductor region PH-S. The first material MAT1 can, for example, be polycrystalline silicon or silicon nitride.

Advantageously, in the case where the first material MAT1 is polycrystalline silicon, step S16 can be carried out simultaneously with a formation of gates of transistors G1, G2, G3, G4, G5, and G6.

Then, a second step S26 comprises etching in the layer of the first material MAT1, for example via a conventional lithography method comprising the use of a mask, so as to form pads projecting relative to the front face FAV of the photosensitive semiconductor region PH-S.

Advantageously, step S26 can be carried out simultaneously with an etching of gates of transistors G1, G2, G3, G4, G5, and G6, in the polycrystalline silicon layer formed in step S16.

A third step S36 then comprises covering the periodic array of projecting pads with a layer of the second material MAT2 PMD-S. The second material MAT2 is for example silicon oxide or silicon nitride (in the case where the first material is not silicon nitride).

Advantageously, the layer of second material MAT2 is a pre-metal dielectric layer, typically provided between the front face FAV of the semiconductor substrate, and the interconnection levels of the integrated circuits.

Thus, the method for manufacturing the periodic array RP-S of projecting pads can be fully co-integrated into manufacturing steps otherwise provided, and thus be free of charge (that is to say, not introduce any additional cost in the context of the manufacture).

FIG. 7 illustrates the steps of a method for manufacturing a periodic array RP-G of pads housed in a front face FAV of a photosensitive semiconductor region PH-G.

A first step S17 comprises etching trenches penetrating into the photosensitive semiconductor region PH-G so as to form an outline CTR of the periodic array.

Then, a second step S27 comprises filling the trenches with a dielectric layer PMD-G comprising a first material MAT1, so as to house the pads in the photosensitive semiconductor region PH-G, and so as to form the “PMD” type dielectric isolating layer.

Advantageously, the steps S17 and S27 can be carried out simultaneously with a method for forming shallow isolation trenches (usually designated by the acronym “STI” from the term “Shallow Trench Isolation”).

In this implementation, the second material MAT2 is the semiconductor material of the photosensitive region PH-G, and forms an interface with the first material MAT1 of the “PMD” type isolating layer, for example made of silicon oxide or silicon nitride. The pads then form an integral part of the “PMD” type dielectric isolating layer.

FIG. 8 illustrates the steps of an alternative manufacturing method to the method presented with reference to FIG. 6, allowing a periodic array RP-G of pads projecting on a front face FAV of a photosensitive semiconductor region PH-S to be obtained.

A first step S18 comprises forming an initial layer from a second material MAT2 on the front face FAV of the photosensitive semiconductor region PH-S. The second material MAT2 can, for example, be silicon oxide or silicon nitride.

A second step S28 comprises etching, for example via a conventional lithography method comprising the use of a mask, trenches penetrating the initial layer of the second material MAT2 so as to form an outline CTR of the periodic array in the layer.

A third step S38 comprises filling the trenches of the initial layer of the second material MAT2, etched in step S28, so as to form a periodic array of pads in the first material MAT1 housed in the etched trenches.

A fourth step S48 comprises covering the periodic array RP-S and the initial layer made of the second material MAT2 with a new layer of the second material MAT2.

Steps S18-S48 described in relation to FIG. 8 can also be part of manufacturing steps already provided in a given industrial manufacturing context, and consequently benefit from a reduced, or even zero cost, for their executions.

1. An electronic device, comprising:
a photosensitive semiconductor region comprising a front face and an opposite rear face, wherein the photosensitive semiconductor region is configured to be illuminated through said rear face; and
a periodic array of pads made of a first material and formed at the front face, said periodic array having an outline with a periodic pattern parameterized by characteristic dimensions, said outline forming an interface between the first material and a second material, the second material having an optical index different from an optical index of the first material;
wherein the characteristic dimensions of the periodic pattern are configured to produce a resonance effect providing a reflection of light at the interface at the wavelength of interest towards the photosensitive semiconductor region, wherein said resonance effect comprises constructive light interference below the front face of the photosensitive semiconductor region and destructive light interference above the front face of the photosensitive semiconductor region.

2. The device according to claim 1, wherein the characteristic dimensions of the periodic pattern are less than a wavelength of interest.

3. The device according to claim 1, wherein the pads project relative to the front face of the photosensitive semiconductor region, the first material is a semiconductor material and the second material belongs to a dielectric layer covering the projecting pads and the front face.

4. The device according to claim 3, further comprising transistors having gate regions made of polycrystalline silicon, wherein the first material for the pads has the same nature and the same thickness as the gate regions of the transistors.

5. The device according to claim 1, wherein the pads are housed in trenches penetrating into the photosensitive semiconductor region, the first material for the pads is a dielectric material filling the trenches and covering the front face of the photosensitive semiconductor region, and the second material is a semiconductor material of the photosensitive semiconductor region.

6. The device according to claim 5, further comprising shallow isolation trenches that penetrating into the photosensitive semiconductor region, and wherein the pads have the same nature and the same depth as said shallow isolation trenches.

7. The device according to claim 1, wherein each pad has a shape of a cylinder including a diameter and a height, and wherein the characteristic dimensions comprise said diameter and said height.

8. The device according to claim 1, wherein the periodic array of pads is disposed in a periodic arrangement comprising an elementary mesh of pads repeated with a fixed period, and wherein the characteristic dimensions comprise said fixed period.

9. The device according to claim 1, wherein the photosensitive semiconductor region is configured to specifically detect light at wavelengths centered on the wavelength of interest.

10. The device according to claim 1, wherein the first material and the second material are selected from the group consisting of the following materials: polycrystalline silicon, silicon oxide, silicon nitride, and monocrystalline silicon; and wherein the difference in optical index produces the reflection of light at the wavelength of interest on the interface in response to the characteristic dimensions of the periodic array.

11. An electronic device, comprising:
a photosensitive semiconductor region comprising a front face and an opposite rear face, wherein the photosensitive semiconductor region is configured to be illuminated through said rear face;
transistors having gate regions made of polycrystalline silicon; and
a periodic array of pads made of a first material and formed at the front face, said periodic array configured to produce at the interface a reflection of light at the wavelength of interest towards the photosensitive semiconductor region, said periodic array further having an outline with a periodic pattern parameterized by characteristic dimensions, said outline forming an interface between the first material and a second material, the second material having an optical index different from an optical index of the first material;
wherein the pads project relative to the front face of the photosensitive semiconductor region, the first material is a semiconductor material and the second material belongs to a dielectric layer covering the projecting pads and the front face; and
wherein the first material for the pads has the same nature and the same thickness as the gate regions of the transistors.

12. The device according to claim 11, wherein the characteristic dimensions of the periodic pattern are less than a wavelength of interest.

13. The device according to claim 11, wherein the pads are housed in trenches penetrating into the photosensitive semiconductor region, the first material for the pads is a dielectric material filling the trenches and covering the front face of the photosensitive semiconductor region, and the second material is a semiconductor material of the photosensitive semiconductor region.

14. The device according to claim 13, further comprising shallow isolation trenches that penetrating into the photosensitive semiconductor region, and wherein the pads have the same nature and the same depth as said shallow isolation trenches.

15. The device according to claim 11, wherein each pad has a shape of a cylinder including a diameter and a height, and wherein the characteristic dimensions comprise said diameter and said height.

16. The device according to claim 11, wherein the periodic array of pads is disposed in a periodic arrangement comprising an elementary mesh of pads repeated with a fixed period, and wherein the characteristic dimensions comprise said fixed period.

17. The device according to claim 11, wherein the photosensitive semiconductor region is configured to specifically detect light at wavelengths centered on the wavelength of interest.

18. The device according to claim 11, wherein the first material and the second material are selected from the group consisting of the following materials: polycrystalline silicon, silicon oxide, silicon nitride, and monocrystalline silicon; and wherein the difference in optical index produces the reflection of light at the wavelength of interest on the interface in response to the characteristic dimensions of the periodic array.

19. A method for manufacturing an electronic device, comprising:
forming a photosensitive semiconductor region having a front face and an opposite rear face that is configured to be illuminated;
forming a periodic array of pads at the front face that are made from a first material; wherein forming the periodic array comprises defining an outline of the periodic array to have a periodic pattern parameterized by characteristic dimensions so as to form an interface between the first material and a second material, the second material having an optical index different from the optical index of the first material;
wherein the characteristic dimensions of the periodic pattern are configured to produce a resonance effect providing a reflection of light at the interface at the wavelength of interest towards the photosensitive semiconductor region, wherein said resonance effect comprises constructive light interference below the front face of the photosensitive semiconductor region and destructive light interference above the front face of the photosensitive semiconductor region

20. The method of claim 19, wherein the characteristic dimensions of the periodic pattern are formed at dimensions less than a wavelength of interest.

21. The method according to claim 19, wherein forming the periodic array of pads comprises:
forming a layer of the first material on the front face of the photosensitive semiconductor region;
etching in the layer of the first material to produce pads projecting relative to the front face of the photosensitive semiconductor region; and
forming a dielectric layer comprising the second material and covering the projecting pads.

22. The method according to claim 19, wherein forming the periodic array of pads comprises:
etching trenches penetrating into the photosensitive semiconductor region comprising the second material to form the outline of the periodic array; and
filling said trenches with a dielectric layer comprising the first material to produce the pads in the trenches.

23. The method according to claim 22, further comprising forming shallow isolation trenches, wherein:
etching of trenches penetrating the photosensitive semiconductor region is carried out simultaneously with an etching of the shallow isolation trenches; and
filling of trenches with a dielectric layer is carried out simultaneously with a filling of the shallow isolation trenches.

24. The method according to claim 19, wherein each pad of the periodic array has a shape of a cylinder including a diameter and a height, and wherein the characteristic dimensions comprise said diameter and said height.

25. The method according to claim 19, wherein the periodic array is formed so that the pads are disposed in a periodic arrangement comprising an elementary mesh of pads repeated with a fixed period, and wherein the characteristic dimensions comprise said fixed period.

26. The method according to claim 19, wherein the photosensitive semiconductor region is configured specifically to detect light at wavelengths centered on the wavelength of interest.

27. The method according to claim 19, wherein the first material and the second material are selected from the group consisting of the following materials: polycrystalline silicon, silicon oxide, silicon nitride, monocrystalline silicon; and wherein the difference in optical index produce the reflection of light at the wavelength of interest on the interface in accordance with the characteristic dimensions of the periodic array.

28. A method for manufacturing an electronic device, comprising:
forming a photosensitive semiconductor region having a front face and an opposite rear face that is configured to be illuminated;
forming gate regions of transistors by:
forming a layer of polycrystalline silicon; and
etching the gate regions of the transistors in the polycrystalline silicon layer;
forming a periodic array of pads at the front face that are made from a first material; wherein forming the periodic array comprises defining an outline of the periodic array to have a periodic pattern parameterized by characteristic dimensions so as to form an interface between the first material and a second material that is configured to produce at the interface a reflection of light at the wavelength of interest towards the photosensitive semiconductor region, the second material having an optical index different from the optical index of the first material;
wherein forming the periodic array of pads comprises:
forming a layer of the first material on the front face of the photosensitive semiconductor region;
etching in the layer of the first material to produce pads projecting relative to the front face of the photosensitive semiconductor region; and
forming a dielectric layer comprising the second material and covering the projecting pads; and
wherein forming the layer of the first material is carried out simultaneously with forming the polycrystalline silicon layer, and wherein etching the layer of the first material is carried out simultaneously with etching of the gate regions of transistors in the polycrystalline silicon layer.

29. The method according to claim 28, wherein the characteristic dimensions of the periodic pattern are formed at dimensions less than a wavelength of interest.

30. The method according to claim 28, further comprising forming shallow isolation trenches, wherein:
etching of trenches penetrating the photosensitive semiconductor region is carried out simultaneously with an etching of the shallow isolation trenches; and
filling of trenches with a dielectric layer is carried out simultaneously with a filling of the shallow isolation trenches.

31. The method according to claim 28, wherein each pad of the periodic array has a shape of a cylinder including a diameter and a height, and wherein the characteristic dimensions comprise said diameter and said height.

32. The method according to claim 28, wherein the periodic array is formed so that the pads are disposed in a periodic arrangement comprising an elementary mesh of pads repeated with a fixed period, and wherein the characteristic dimensions comprise said fixed period.

33. The method according to claim 28, wherein the photosensitive semiconductor region is configured specifically to detect light at wavelengths centered on the wavelength of interest.

34. The method according to claim 28, wherein the first material and the second material are selected from the group consisting of the following materials: polycrystalline silicon, silicon oxide, silicon nitride, monocrystalline silicon; and wherein the difference in optical index produce the reflection of light at the wavelength of interest on the interface in accordance with the characteristic dimensions of the periodic array.
